(19) United States
(12) Patent Application Publication
(10) Pub. No.: US 2026/0333959 A1
(43) Pub. Date: Oct. 22, 2026

(54) LIGHT-EMITTING DEVICE

(71) Applicant: HUIZHOU JUFEI OPTOELECTRONICS CO., LTD., Huizhou (CN)

(72) Inventors: Pingru SUN, Huizhou (CN); Wenbo MA, Huizhou (CN); Meizheng XING, Huizhou (CN)

(73) Assignee: HUIZHOU JUFEI OPTOELECTRONICS CO., LTD., Huizhou (CN)

(21) Appl. No.: 19/724,353

(22) Filed: Jun. 29, 2026

Related U.S. Application Data
(63) Continuation of application No. PCT/CN2025/070523, filed on Jan. 3, 2025.

(30) Foreign Application Priority Data
Jan. 5, 2024 (CN) 202410020423.3
Jan. 30, 2024 (CN) 202410129782.2
Jan. 30, 2024 (CN) 202420232897.X

(51) Int. Cl. H10H 20/855; H10H 20/01; H10H 20/85; H10H 20/853; H10H 20/854; H10H 20/856; H10H 20/857

(52) U.S. Cl. CPC H10H 20/855; H10H 20/0362; H10H 20/0363; H10H 20/8502; H10H 20/853; H10H 20/854; H10H 20/856; H10H 20/857

(57) ABSTRACT

The present invention relates to a light-emitting device including a circuit board and a light-emitting unit disposed thereon. The light-emitting unit includes an LED light source and an encapsulating lens covering the LED light source. The encapsulating lens has an arc-shaped light-emitting surface with a convex or concave top portion for adjusting the light-emitting pattern. The invention improves luminous efficiency for display backlight sources and lighting devices.

### TECHNICAL FIELD

The present invention relates to the field of semiconductor light-emitting devices, and more particularly, to a light-emitting device.

### BACKGROUND

Light Emitting Diodes (LEDs), as semiconductor light-emitting devices widely used in fields such as illumination and display as LED light sources, include a light-emitting chip having a P-N junction as a light-emitting component thereof. By applying a voltage to electrodes of the light-emitting chip, electrons and holes therein recombine and radiate energy, thereby emitting visible light.

In the related art, LEDs are typically fabricated as packaged devices, which may also be referred to as LED surface-mount devices (SMDs). During use, the packaged devices are mounted and soldered onto a Printed Circuit Board (PCB). Improving connection reliability between the LED devices and the PCB, as well as enhancing light extraction efficiency, has become an important direction for technological development.

The present application provides a light-emitting device configured to improve connection reliability and/or light extraction efficiency of an LED light source. The light-emitting device provided in the present application includes a circuit substrate and a light-emitting unit disposed on a front surface of the circuit substrate. The light-emitting unit includes an LED light source disposed on the front surface of the circuit substrate and electrically connected to corresponding pads on the front surface of the circuit substrate, and an encapsulation lens disposed on the front surface of the circuit substrate and covering the LED light source. The LED light source includes a bottom surface, a top surface, and side surfaces. The bottom surface is adjacent to the front surface of the circuit substrate. The top surface is away from the front surface of the circuit substrate and serves as a top light-emitting surface. The side surfaces are located between the bottom surface and the top surface and serve as side light-emitting surfaces. The encapsulation lens has an arcuate light-emitting surface configured to adjust a light distribution pattern of the light-emitting unit. A top portion of the encapsulation lens is convex or concave.

In some embodiments, a ratio of a first maximum distance H1 between the light-emitting surface of the encapsulation lens and the front surface of the circuit substrate to a second maximum distance H2 between the top light-emitting surface of the LED light source and the front surface of the circuit substrate is 1.5 to 10, and a ratio of a first maximum width W1 of the encapsulation lens to H1 is 0.75 to 5.3.

In some embodiments, the light-emitting device further includes a filling layer. The filling layer at least fills a gap between the bottom surface of the LED light source and the circuit substrate and is bonded to at least the bottom surface and side surfaces of the LED light source. The encapsulation lens covers the filling layer and the LED light source. The filling layer is formed of a first adhesive material, and the encapsulation lens is formed of a second adhesive material different from the first adhesive material, wherein the first adhesive material has a hardness less than or equal to that of the second adhesive material.

At least some embodiments provided in the present application may improve connection reliability and/or light extraction efficiency of the LED light source. The present invention is described in further detail below with reference to the accompanying drawings and specific embodiments, which are provided for illustrative purposes only and are not intended to limit the present invention.

### BRIEF DESCRIPTION OF DRAWINGS

FIG. 1 is a schematic structural view of a light-emitting device according to Embodiment 1 of the present invention;

FIGS. 2-1 to 2-3 are schematic structural views of the light-emitting device according to Embodiment 1 of the present invention;

FIG. 3 is a schematic structural view of the light-emitting device according to Embodiment 1 of the present invention;

FIG. 4 is a schematic structural view of the light-emitting device according to Embodiment 1 of the present invention;

FIG. 5 is a schematic structural view of the light-emitting device according to Embodiment 1 of the present invention;

FIG. 6 is a schematic structural view of the light-emitting device according to Embodiment 1 of the present invention;

FIGS. 7-1 and 7-2 are schematic views respectively illustrating light distribution patterns of the light-emitting device shown in FIG. 6;

FIG. 8 is a schematic structural view of the light-emitting device according to Embodiment 1 of the present invention;

FIG. 9 is a schematic structural view of the light-emitting device according to Embodiment 1 of the present invention;

FIGS. 10-1 and 10-2 are schematic views respectively illustrating light distribution patterns of the light-emitting device shown in FIG. 9;

FIG. 11 is a schematic structural view of the light-emitting device according to Embodiment 1 of the present invention;

FIGS. 12-1 and 12-2 are schematic views respectively illustrating light distribution patterns of the light-emitting device shown in FIG. 11;

FIG. 13 is a schematic structural view of the light-emitting device according to Embodiment 1 of the present invention;

FIG. 14-1 is a schematic structural view of the light-emitting device according to Embodiment 1 of the present invention;

FIG. 14-2 is a schematic structural view of a conductive pad structure of the light-emitting device shown in FIG. 14-1;

FIG. 15 is a schematic structural view of the light-emitting device according to Embodiment 1 of the present invention;

FIG. 16-1 is a schematic structural view of the light-emitting device according to Embodiment 1 of the present invention;

FIG. 16-2 is a schematic structural view of a circuit substrate of the light-emitting device shown in FIG. 16-1;

FIG. 17-1 is a schematic structural view of the light-emitting device according to Embodiment 1 of the present invention;

FIG. 17-2 is a schematic structural view of a circuit substrate of the light-emitting device shown in FIG. 17-1;

FIG. 18 is a schematic structural view of the light-emitting device according to Embodiment 1 of the present invention;

FIG. 19 is a schematic structural view of a light-emitting device according to Embodiment 2 of the present invention;

FIG. 20 is a schematic structural view of the light-emitting device according to Embodiment 2 of the present invention;

FIG. 21 is a schematic structural view of the light-emitting device according to Embodiment 2 of the present invention;

FIG. 22 is a schematic structural view of the light-emitting device according to Embodiment 2 of the present invention;

FIG. 23 is a schematic structural view of the light-emitting device according to Embodiment 2 of the present invention;

FIG. 24 is a schematic flowchart illustrating a method for manufacturing the light-emitting device according to Embodiment 2 of the present invention;

FIG. 25 is a first schematic structural view of the light-emitting device according to Embodiment 1 of the present utility model;

FIG. 26 is a schematic structural view of a light-emitting device in the related art;

FIG. 27 is a schematic structural view of the light-emitting device according to Embodiment 1 of the present utility model;

FIG. 28 is a schematic structural view of the light-emitting device according to Embodiment 1 of the present utility model;

FIG. 29 is a schematic structural view of the light-emitting device according to Embodiment 1 of the present utility model; and

FIG. 30 is a schematic structural view of the light-emitting device according to Embodiment 1 of the present utility model.

### DESCRIPTION OF EMBODIMENTS

To facilitate understanding of the present application, the present application will be described more fully below with reference to the accompanying drawings. Preferred embodiments of the present application are illustrated in the accompanying drawings. However, the present application may be embodied in many different forms and is not limited to the embodiments described herein. Rather, these embodiments are provided so that the disclosure of the present application will be more thorough and complete. Those of ordinary skill in the art will appreciate that various modifications, combinations, or adjustments may be made to the embodiments of the present invention without departing from the scope and spirit of the present invention. Unless otherwise defined, all technical and scientific terms used herein have the same meanings as commonly understood by those skilled in the art to which the present application pertains. The terminology used in the specification of the present application is for the purpose of describing particular embodiments only and is not intended to limit the present application. References in this specification to “one embodiment,” “an embodiment,” “some embodiments,” or similar expressions are not necessarily directed to the same embodiment.

### Embodiment 1

The present embodiment provides a light-emitting device having a batwing-like light distribution characteristic capable of suppressing light intensity directly above the device while increasing light intensity emitted from side regions, thereby enlarging the light-emitting angle and reducing luminance non-uniformity and related issues. Accordingly, illumination performance of a lighting device incorporating the light-emitting device and display performance of a display device incorporating the light-emitting device may be improved.

The present embodiment provides a light-emitting device in which a height of a top light-emitting surface of an LED light source relative to a circuit substrate is appropriately elevated and combined with an encapsulation lens having a specific height and width, such that the light-emitting device exhibits a batwing-like light distribution characteristic.

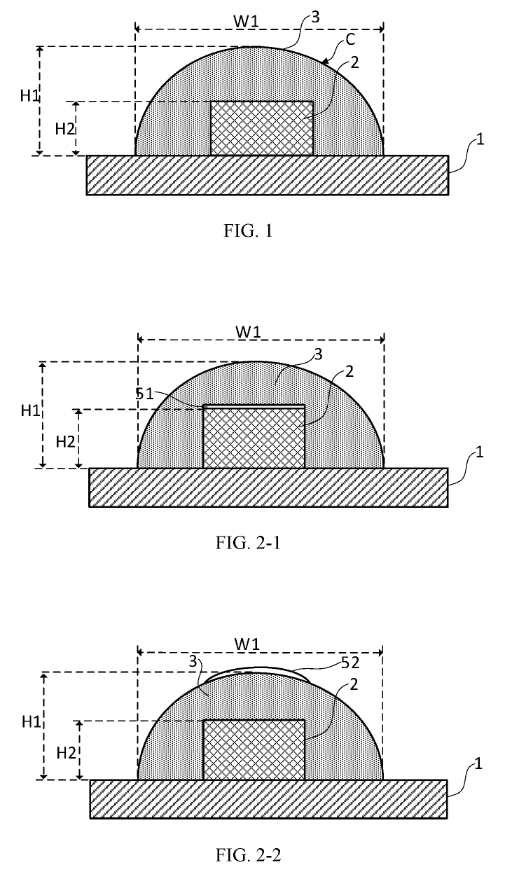

Referring to FIG. 1, the light-emitting device provided in the present embodiment includes a circuit substrate 1 and a light-emitting unit disposed on a front surface of the circuit substrate 1. The light-emitting unit includes an LED light source 2 disposed on the front surface of the circuit substrate 1 and electrically connected to corresponding pads on the front surface of the circuit substrate 1, and an encapsulation lens 3 disposed on the front surface of the circuit substrate 1 and covering the LED light source 2. The LED light source 2 includes a bottom surface, a top surface, and side surfaces. The bottom surface is adjacent to the circuit substrate 1, the top surface is away from the front surface of the circuit substrate 1 and serves as a top light-emitting surface, and the side surfaces are located between the bottom surface and the top surface and serve as side light-emitting surfaces.

In the present embodiment, both the top surface and the side surfaces of the LED light source 2 are capable of emitting light. When the LED light source 2 has an overall cube or rectangular parallelepiped shape, the LED light source 2 is a five-sided light-emitting source. When the LED light source 2 has an overall cylindrical shape, the LED light source 2 emits light from the cylindrical side surface and the top surface. The LED light source 2 in the present embodiment is a multi-surface light-emitting source that emits light from both side surfaces and the top surface. Compared with conventional light sources that emit light only from a top surface, the LED light source 2 has higher light extraction efficiency and light utilization efficiency, and can reduce differences in light intensity between top-surface regions and side-surface regions at the source, thereby facilitating realization of a batwing-like light distribution characteristic by the light-emitting unit.

In the present embodiment, a light-emitting surface of the encapsulation lens 3 is an arcuate surface C. A maximum distance between the light-emitting surface of the encapsulation lens 3 and the front surface of the circuit substrate 1 is defined as a first maximum distance H1. A maximum distance between the top light-emitting surface of the LED light source 2 and the front surface of the circuit substrate 1 is defined as a second maximum distance H2. A ratio of H1 to H2 is 1.5 to 10 (inclusive). A maximum width of the encapsulation lens 3 is defined as a first maximum width W1, and a ratio of W1 to H1 is 0.75 to 5.3 (inclusive).

In the present embodiment, H1 may have a range including, but not limited to, 1.5 mm to 4.0 mm. In other embodiments, the range of H1 may alternatively be 1.5 mm to 2.0 mm, 2.0 mm to 2.5 mm, 2.5 mm to 3.0 mm, 3.0 mm to 4.0 mm, 1.5 mm to 3.5 mm, 3.5 mm to 4.0 mm, 1.5 mm to 2.5 mm, 2.5 mm to 4.0 mm, or the like.

In the present embodiment, H2 may have a range of 0.4 mm to 1.0 mm. In other embodiments, the range of H2 may alternatively be 0.4 mm to 0.5 mm, 0.5 mm to 0.6 mm, 0.6 mm to 0.7 mm, 0.7 mm to 0.8 mm, 0.8 mm to 0.9 mm, 0.9 mm to 1.0 mm, 0.4 mm to 0.8 mm, 0.5 mm to 0.8 mm, 0.7 mm to 1.0 mm, 0.8 mm to 1.0 mm, 0.4 mm to 0.6 mm, 0.5 mm to 0.7 mm, 0.6 mm to 1.0 mm, or the like.

In the present embodiment, W1 may have a range including, but not limited to, 3.0 mm to 8.0 mm. In other embodiments, the range of W1 may alternatively be 3.0 mm to 4.0 mm, 4.0 mm to 5.0 mm, 5.0 mm to 6.0 mm, 6.0 mm to 7.0 mm, 7.0 mm to 8.0 mm, 3.0 mm to 6.0 mm, 3.5 mm to 6.5 mm, 5.0 mm to 8.0 mm, 3.0 mm to 5.0 mm, 5.0 mm to 7.0 mm, 6.0 mm to 8.0 mm, or the like.

In the present embodiment, the ratio of H1 to H2 may range from 1.5 to 10. In other embodiments, the ratio of H1 to H2 may alternatively range from 1.5 to 3.0, 1.5 to 2.0, 1.5 to 3.5, 2.0 to 3.0, 2.0 to 3.5, 3.0 to 5.0, 5.0 to 7.0, 7.0 to 8.5, 8.5 to 10, 1.5 to 5.0, 5.0 to 8.0, 8.0 to 10, 1.5 to 7.0, 5.0 to 10, 1.5 to 4.0, 4.0 to 8.0, 6.0 to 8.0, 6.0 to 7.0, 6.0 to 10.0, 6.0 to 9.0, 7.0 to 9.0, 7.0 to 10.0, or the like.

In the present embodiment, the ratio of W1 to H1 may range from 0.75 to 5.3. In other embodiments, the ratio of W1 to H1 may alternatively range from 0.75 to 1.0, 0.75 to 1.5, 0.75 to 1.8, 0.75 to 2.0, 1.0 to 1.5, 1.0 to 2.0, 1.0 to 2.5, 2.5 to 5.0, 5.0 to 5.3, 4.0 to 5.3, 2.0 to 5.3, 0.75 to 1.5, 1.5 to 3, 3 to 5.3, or the like.

In one preferred embodiment, H1 is 2.26 mm, H2 is 0.6 mm, and W1 is 5.5 mm. Such a combination can achieve an improved light distribution characteristic.

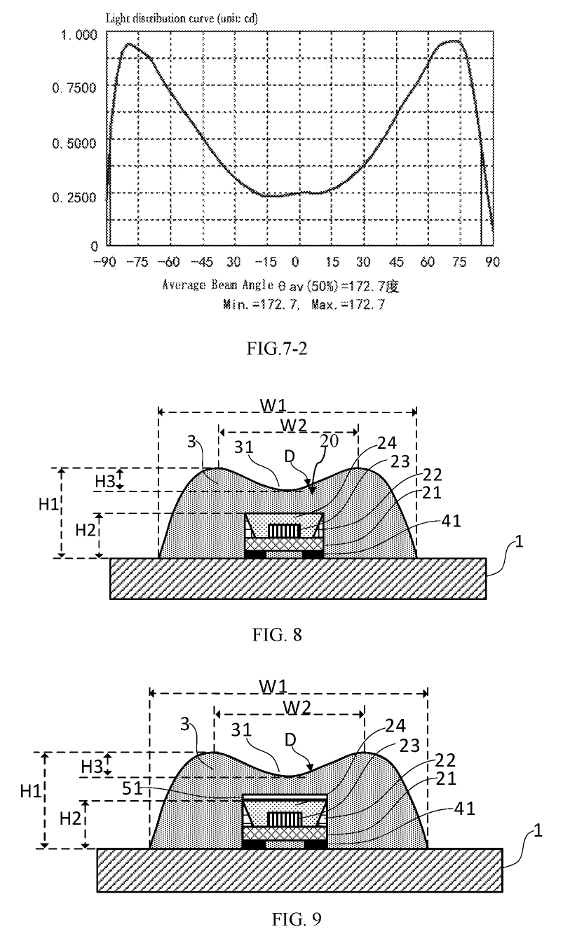

In the present embodiment, the light-emitting surface of the encapsulation lens 3 is configured as an arcuate surface, and the ratio of W1 to H1 is set to 0.75 to 5.3, such that the encapsulation lens 3 has a specific shape. In addition, the ratio of H1 to H2 is set to 1.5 to 10, such that the top light-emitting surface and the side light-emitting surfaces of the LED light source 2 are positioned at appropriate locations within the encapsulation lens, and incident angles at which light emitted from the top light-emitting surface and the side light-emitting surfaces enters the light-emitting surface of the encapsulation lens 3 fall within a predetermined range. As a result, after passing through the encapsulation lens 3, the emitted light exhibits a batwing-like light distribution characteristic. That is, the light distribution curve of the light-emitting unit exhibits a batwing-like distribution pattern, as shown, for example, in FIGS. 7-1 and 7-2.

The light-emitting device of the present embodiment can achieve a batwing-like light distribution characteristic merely through a specific combination of the LED light source 2 and the encapsulation lens 3, thereby providing an extremely simple structure, low cost, ease of manufacture, and good versatility.

It should be understood that the base material of the circuit substrate 1 in the present embodiment may include, but is not limited to, ceramic, resin, or glass. The circuit substrate 1 may be a rigid substrate or a flexible substrate. For example, the circuit substrate 1 may include, but is not limited to, a rigid PCB board or an FPC circuit board. In the present embodiment, the pads on the front surface of the circuit substrate 1 may be electrically connected to the LED light source 2 by, for example, solder bonding or conductive adhesive bonding, although other connection methods may also be used.

In the present embodiment, the light-emitting unit further includes a reflective layer disposed over the top light-emitting surface of the LED light source 2. The reflective layer is configured to reflect a portion of light emitted from the top light-emitting surface while allowing another portion of the light emitted from the top light-emitting surface to pass therethrough. In this configuration, a portion of the light emitted from the top light-emitting surface of the LED light source 2 is reflected by the reflective layer such that the reflected light is emitted from the side surfaces of the LED light source 2, thereby appropriately suppressing light intensity emitted from the top light-emitting surface of the LED light source 2 and enlarging the light-emitting angle of the LED light source 2. As a result, the batwing-like light distribution characteristic of the light-emitting unit may be further optimized.

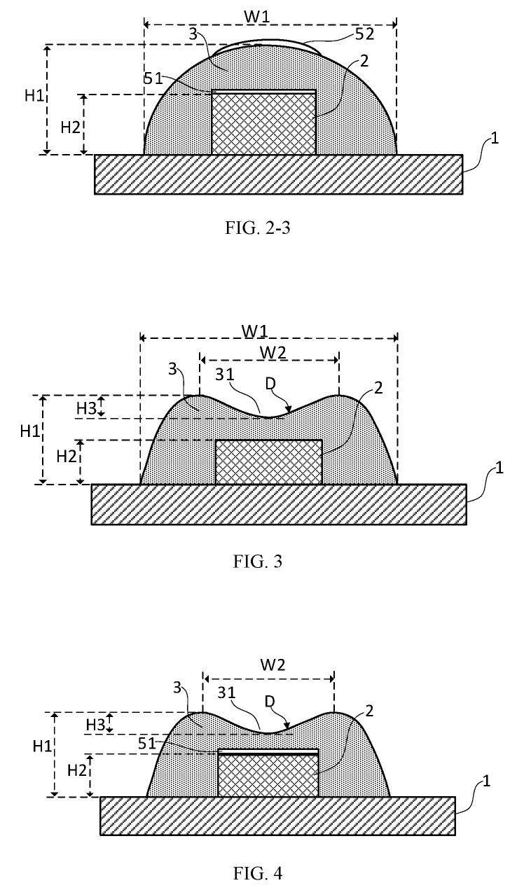

Referring to the light-emitting device shown in FIG. 2-1, compared with the light-emitting device shown in FIG. 1, the primary difference is that the light-emitting device further includes a first reflective layer 51 disposed over the top light-emitting surface of the LED light source 2. The first reflective layer 51 is located between the LED light source 2 and the encapsulation lens 3 and covers the top light-emitting surface of the LED light source 2. The first reflective layer 51 may completely cover the top light-emitting surface of the LED light source 2 as needed, or may partially cover the top light-emitting surface with respect to a center thereof.

Referring to the light-emitting device shown in FIG. 2-2, compared with the light-emitting device shown in FIG. 2-1, the primary difference is that the reflective layer in this example includes a second reflective layer 52 disposed on the light-emitting surface of the encapsulation lens 3 and corresponding in position to the top light-emitting surface of the LED light source 2. The projection of the second reflective layer 52 onto the top light-emitting surface of the LED light source 2 may completely cover the top light-emitting surface of the LED light source 2 as needed, or may partially cover the top light-emitting surface with respect to a center thereof. In one example, the light-emitting device may simultaneously include both the first reflective layer 51 and the second reflective layer 52, as shown in FIG. 2-3.

In the present example, the first reflective layer 51 and the second reflective layer 52 include light-transmissive particles. For example, the light-transmissive particles may be hollow glass microspheres. The glass microspheres reflect and refract light such that light directly above the light-emitting device is reflected and refracted toward side regions by the light-transmissive particles, thereby increasing light intensity in side regions of the LED light source 2 while still allowing a portion of the light to be emitted from the top light-emitting surface of the LED light source 2. Such a configuration is suitable for applications in which the light intensity emitted from the top light-emitting surface of the LED light source 2 should not be excessively weak. The light-transmissive particles may alternatively include other transparent or semi-transparent particles.

In other examples, the first reflective layer 51 and the second reflective layer 52 may include opaque reflective particles, such as titanium dioxide particles or barium sulfate particles. The first reflective layer 51 and the second reflective layer 52 may also include a mixture of opaque reflective particles and light-transmissive particles, such as a mixture of titanium dioxide particles and glass microspheres, a mixture of barium sulfate particles and glass microspheres, or a mixture of titanium dioxide particles, barium sulfate particles, and glass microspheres. Titanium dioxide particles and barium sulfate particles exhibit higher reflectivity than glass microspheres. Accordingly, when the first reflective layer 51 or the second reflective layer 52 contains only titanium dioxide particles, barium sulfate particles, or a mixture thereof, stronger shielding of light emitted from the top light-emitting surface of the LED light source 2 may be achieved, making such configurations more suitable for applications requiring stronger light intensity at side regions of the LED light source 2 and weaker light intensity at central regions. Because gaps may still exist between particles, some light may nevertheless be emitted from the top light-emitting surface of the LED light source 2.

When the first reflective layer 51 or the second reflective layer 52 includes a mixture of titanium dioxide particles or barium sulfate particles with glass microspheres, or a mixture of titanium dioxide particles, barium sulfate particles, and glass microspheres, the proportion of the glass microspheres may be used to adjust the light intensity emitted from the top light-emitting surface of the LED light source 2. A higher proportion of glass microspheres in the first reflective layer 51 or the second reflective layer 52 results in greater light intensity emitted from the top light-emitting surface of the LED light source 2. Accordingly, the light intensity emitted from the top light-emitting surface of the LED light source 2 may be adjusted by controlling the proportion of glass microspheres in the first reflective layer 51 or the second reflective layer 52.

### Embodiment 2

Referring to FIG. 3, a region of the light-emitting surface of the encapsulation lens 3 corresponding to the top light-emitting surface of the LED light source 2 is provided with a recessed portion 31 recessed toward the top light-emitting surface. A surface of the recessed portion 31 is an arcuate surface D. The recessed portion 31 forms a concave lens-like structure capable of increasing an incident angle of light emitted from the top light-emitting surface of the LED light source 2. By utilizing a characteristic that total internal reflection readily occurs when light travels from an optically denser medium to an optically less dense medium (e.g., air), a propagation direction of such light may be altered, thereby enlarging a light-emitting angle of the LED light source 2 and appropriately suppressing light intensity emitted from the top light-emitting surface of the LED light source 2, thereby further optimizing the batwing-like light distribution characteristic of the light-emitting unit.

Optionally, in the present embodiment, a ratio of a second maximum width W2 of the recessed portion 31 to a maximum depth H3 of the recessed portion 31 may be set to 0.62 to 50 (inclusive). In combination with the above-described specific ratios of H1, H2, and W1, the batwing-like light distribution characteristic of the light-emitting unit may be maximally optimized. For example, W2 may range from 0.5 mm to 2.5 mm (inclusive), and H3 may range from 0.05 mm to 0.8 mm (inclusive).

In the present embodiment, W2 may range from 0.5 mm to 2.5 mm. In other embodiments, the range of the second maximum width W2 may alternatively be 0.5 mm to 0.8 mm, 0.8 mm to 1.0 mm, 1.0 mm to 1.2 mm, 1.2 mm to 1.4 mm, 1.4 mm to 1.6 mm, 1.6 mm to 1.8 mm, 1.8 mm to 2.0 mm, 2.0 mm to 2.4 mm, 0.5 mm to 1.0 mm, 1.0 mm to 2.0 mm, 2.0 mm to 2.5 mm, or the like.

In the present embodiment, H3 may range from 0.05 mm to 0.8 mm. In other embodiments, the range of H3 may alternatively be 0.05 mm to 0.1 mm, 0.15 mm to 0.2 mm, 0.25 mm to 0.3 mm, 0.35 mm to 0.4 mm, 0.45 mm to 0.5 mm, 0.5 mm to 0.6 mm, 0.6 mm to 0.7 mm, 0.7 mm to 0.8 mm, 0.05 mm to 0.2 mm, 0.2 mm to 0.4 mm, 0.4 mm to 0.8 mm, 0.6 mm to 0.8 mm, 0.4 mm to 0.6 mm, or the like.

In the present embodiment, the ratio of W2 to H3 may range from 0.62 to 50. In other embodiments, the ratio of W2 to H3 may alternatively range from 0.62 to 10, 10 to 20, 20 to 30, 30 to 40, 40 to 50, 10 to 40, 45 to 50, 5.0 to 20, 10 to 30, 0.62 to 15, 15 to 30, 30 to 50, or the like.

In one preferred embodiment, H3 is 0.4 mm and W2 is 4.8 mm. Such a combination may achieve an improved light distribution characteristic.

In a more preferred embodiment, H1 is 2.26 mm, H2 is 0.6 mm, W1 is 5.5 mm, H3 is 0.4 mm, and W2 is 4.8 mm. Such a combination may achieve a further improved light distribution characteristic.

In the present embodiment, the light-emitting device may further include a first reflective layer 51 disposed on the top light-emitting surface of the light-emitting element, as shown in FIG. 4. Specific dimensions, shapes, and the like of the first reflective layer 51 and the recessed portion 31 may be adjusted according to application requirements. In addition, based on the examples shown in FIGS. 3 and 4, the second reflective layer 52 may also be disposed in, but is not limited to, the recessed portion 31.

Optionally, in the present embodiment, the encapsulation lens 3 is a gel lens formed on the front surface of the circuit substrate 1 using a light-transmissive encapsulating material, which may be any encapsulating material capable of forming a lens. The gel lens is tightly bonded to the front surface of the circuit substrate 1 and the surface of the LED light source 2, as shown, for example, in FIGS. 1 to 4, thereby improving reliability of fixation of the encapsulation lens 3 and enhancing hermetic sealing between the encapsulation lens 3, the circuit substrate 1, and the LED light source 2. As a result, ingress of external moisture into the encapsulation lens 3 and damage to the LED light source 2 may be avoided, thereby improving overall reliability of the light-emitting device.

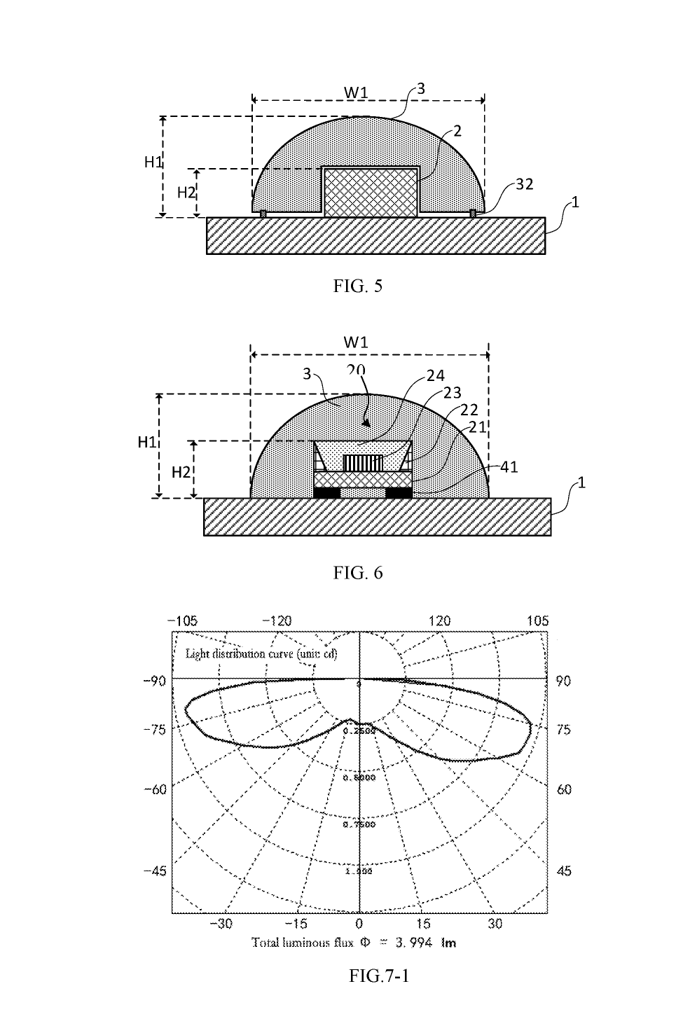

Of course, in the present embodiment, the encapsulation lens 3 may alternatively be fabricated in advance and then mounted onto the circuit substrate 1 by various methods so as to cover the LED light source 2. In such cases, the encapsulation lens 3 may be formed of, for example, gel material, plastic, or glass. For example, as shown in FIG. 5, the encapsulation lens 3 may be mounted to the circuit substrate 1 through lens fixing legs 32. In this arrangement, a gap exists between the encapsulation lens 3 and the LED light source 2, which is disadvantageous for hermetic sealing. However, it should be noted that the present application does not exclude such a configuration. This configuration has advantages including mature manufacturing processes and low cost, and is also suitable for application scenarios in which hermetic sealing requirements can be satisfied. Such a configuration also provides an advantage in causing the light distribution curve of the light-emitting unit to approach a batwing-like distribution pattern.

### Embodiment 3

Referring to FIG. 6, the LED light source 2 is an LED package 20 capable of emitting light from both top and side surfaces. The LED package 20 includes an LED support 22 having light-transmissive side surfaces and an LED chip 23. A support substrate 21 is disposed at a bottom portion of the LED support 22, wherein the support substrate 21 may serve as a structure for elevating the top light-emitting surface of the LED light source 2. In this elevation arrangement, the LED package 20 may be directly soldered or adhesively bonded to corresponding pads on the front surface of the circuit substrate 1, thereby appropriately elevating the height of the top light-emitting surface of the LED light source 2 relative to the circuit substrate 1. It should be understood that the support substrate 21 may employ various substrate structures used in existing LED supports and may also be thickened as needed, and thus details thereof will not be repeated herein.

In the present example, the LED support 22 is a cup-shaped enclosure 22 having light-transmissive side surfaces. The support material may include transparent or semi-transparent SMC, EMC, PCT, or other suitable materials. Preferably, the support substrate 21 is a light-transmissive substrate, such that a portion of light may also be emitted from a bottom portion of the LED light source 2, thereby improving light utilization efficiency.

The cup-shaped enclosure 22 is disposed on the support substrate 21. The LED chip 23, which may include one chip or two or more chips having identical or different colors depending on application requirements, is located at a bottom portion of the cup-shaped enclosure 22 and disposed on the support substrate 21. An encapsulating adhesive layer 24 is filled within the cup-shaped enclosure 22 and covers the LED chip 23. Specifically, the encapsulating adhesive layer 24 may be tightly bonded to an inner wall of the cup-shaped enclosure 22 and surfaces of the LED chip 23, thereby improving hermetic sealing.

In the present example, the top surface and side surfaces of the LED package serve respectively as the top light-emitting surface and the side light-emitting surfaces of the LED light source 2. In addition, side surfaces and the top surface of the LED chip 23 may all be configured to emit light so as to further improve light extraction efficiency and lighting performance. Alternatively, depending on application requirements, the LED chip 23 may be configured to emit light only from the top surface or only from the side surfaces. For example, a light-emitting chip including a DBR reflective layer may reflect light directed toward the top surface to the side surfaces, thereby achieving side-surface-only light emission. Such chips are commonly referred to in the industry as DBR light-emitting chips.

In the present example, the encapsulating adhesive layer 24 may be a transparent adhesive layer. Optionally, according to specific application requirements, the encapsulating adhesive layer 24 may further include a light color conversion material, including but not limited to phosphor and/or quantum dots, and/or a light diffusion material, such as silica particles. Optionally, in order to maintain substantially similar or consistent stress characteristics between the encapsulating adhesive layer 24 and the light-transmissive encapsulating material forming the lens, both may be formed of silicone-based adhesive layers, thereby avoiding cracking at an interface therebetween due to heating and further improving reliability.

In the present example, an adhesive forming the encapsulating adhesive layer 24 has a first refractive index n1, and an adhesive forming the light-transmissive encapsulating material of the lens 3 has a second refractive index n2, wherein n1≧n2. Preferably, n1 and n2 each range from 1.43 (inclusive) to 1.58 (inclusive). For example, n1 may range from 1.53 to 1.58, and n2 may range from 1.43 to 1.53. By configuring n1≧n2, when light travels from the encapsulating adhesive layer 24 into the lens 3, a diffusion angle of the light does not contract and may even increase, thereby improving light output.

In the present example, the LED package 20 is fixed to pads on the front surface of the circuit substrate 1 through a conductive connection layer 41. In the present example, H2 is primarily determined by a thickness of the conductive connection layer 41 (including the pads on the front surface of the circuit substrate 1 and positive and negative electrode leads at the bottom of the LED package), a thickness of the support substrate 21, and a height of the cup-shaped enclosure 22 (or a thickness of the encapsulating adhesive layer 24). Accordingly, by flexibly configuring at least one of the above dimensions, the top light-emitting surface may be elevated to the height H2. Existing LED packaging structures and manufacturing processes may be directly employed, thereby providing good versatility and low cost.

Light distribution patterns of the light-emitting device shown in FIG. 6 are illustrated in FIGS. 7-1 and 7-2, respectively. The illustrated patterns are typical batwing-like light distribution patterns in which light intensity is highest near ±75°, a central region is dimmer than peripheral regions, and the light-emitting angle is large. When applied in backlight applications, such a light distribution pattern is advantageous for achieving improved optical performance and a higher pitch/OD ratio, where the pitch/OD ratio may be greater than 3. Accordingly, the number of light-emitting units may be significantly reduced, thereby simplifying structure and lowering cost.

When applied in lighting applications, such as lighting for libraries or supermarkets, the batwing-like light distribution pattern facilitates directing light toward bookshelves or merchandise shelves on both sides, rather than wasting most of the light on floor regions between the shelves as in conventional Lambertian light distributions. In applications such as offices, schools, or hospitals, panel lights fabricated using light-emitting devices having batwing-like light distribution patterns may provide highly uniform planar illumination with reduced or prevented glare, thereby facilitating healthy lighting. In plant lighting applications, more uniform illumination may also be provided. In addition, because of the wider illumination angle range, spacing between lighting devices may be increased, thereby reducing the number of lighting devices required and lowering cost.

Optionally, in the present embodiment, the light-emitting device shown in FIG. 6 may be optimized using any one of Optimization Modes 1 to 3 described in the foregoing embodiments, depending on application requirements.

In one example, referring to the light-emitting device shown in FIG. 8, a recessed portion 31 is formed in a region of the light-emitting surface of the encapsulation lens 3 corresponding to the top light-emitting surface of the LED package. A surface of the recessed portion 31 is an arcuate surface capable of changing a propagation direction of light emitted from the top light-emitting surface of the LED package, enlarging a light-emitting angle of the LED package, appropriately suppressing light intensity emitted from the top light-emitting surface of the LED package, and further optimizing the batwing-like light distribution characteristic of the light-emitting unit.

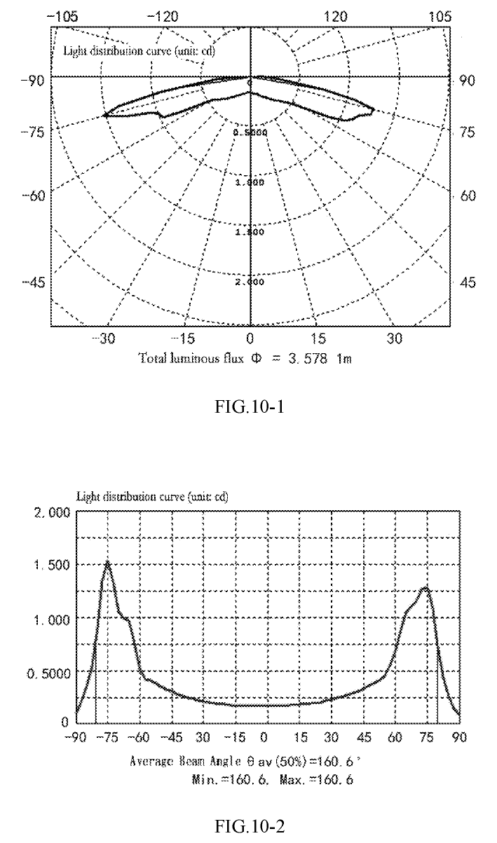

Referring to the light-emitting device shown in FIG. 9, a first reflective layer 51 is disposed over the top light-emitting surface of the LED package 20. The first reflective layer 51 may reflect a portion of light emitted from the top light-emitting surface such that reflected light is emitted from side surfaces of the LED package, thereby appropriately suppressing light intensity emitted from the top light-emitting surface of the LED package 20 and enlarging a light-emitting angle of the LED package, further optimizing the batwing-like light distribution characteristic of the light-emitting unit. Light distribution patterns of the light-emitting device shown in FIG. 9 are illustrated in FIGS. 10-1 and 10-2. Compared with the light distribution patterns shown in FIGS. 7-1 and 7-2, the low-intensity central region is wider, the light intensity at the center is lower, and the light intensity at both side regions is higher.

Of course, it should be understood that, in the present embodiment, the light-emitting device shown in FIG. 6 may alternatively be optimized using only any one of the examples of Optimization Mode 1 described in Embodiment 1, and details thereof will not be repeated herein. In addition, the above-described parameters and ratio values of the present embodiment are also applicable to other embodiments of the present application.

In another example, as shown in FIG. 11, conductive spacers are disposed between bottom electrodes of a conventional LED light-emitting device and the front surface of the circuit substrate 1, thereby appropriately elevating a height of the top light-emitting surface of the LED light source 2 relative to the circuit substrate 1. In the present elevation arrangement, the LED light-emitting device may include at least one of an LED chip capable of emitting light from both side surfaces and a top surface, or an LED package capable of emitting light from both side surfaces and a top surface, such as a CSP (Chip Scale Package) LED package, an NCSP (Near Chip Scale Package) LED package, or another type of LED package.

In the present example, the LED light-emitting device is the LED chip 23. In other embodiments, the LED light-emitting device may alternatively be replaced with a CSP LED package, an NCSP LED package, or another conventional LED package.

In the present example, the conductive spacers include a first conductive spacer 251 and a second conductive spacer 252 electrically insulated from each other. A first electrode and a second electrode of the LED chip 23 (i.e., the LED light-emitting device) are respectively fixedly and electrically connected to front surfaces of the first conductive spacer 251 and the second conductive spacer 252, and back surfaces of the first conductive spacer 251 and the second conductive spacer 252 are respectively fixedly and electrically connected to corresponding pads on the front surface of the circuit substrate 1. As shown in FIG. 11, the back surfaces of the first conductive spacer 251 and the second conductive spacer 252 are respectively fixedly and electrically connected to corresponding pads on the front surface of the circuit substrate 1 through conductive connection layers 42, and the first electrode and the second electrode of the LED chip 23 are respectively fixedly and electrically connected to the front surfaces of the first conductive spacer 251 and the second conductive spacer 252 through conductive connection layers 43. Side surfaces and the top surface of the LED chip 23 in the present example are all capable of emitting light. For ease of distinction, the conductive connection layer 42 and the conductive connection layer 43 may respectively be referred to as a first conductive layer 42 and a second conductive layer 43.

In the example shown in FIG. 11, H2 is primarily determined by a thickness of the second conductive connection layer 42 (including the pads), thicknesses of the first conductive spacer 251 and the second conductive spacer 252, and a thickness of the third conductive connection layer 43. Accordingly, by flexibly configuring at least one of the above dimensions, the top light-emitting surface may be elevated to the height H2. In addition, commercially available LED chips 23 may be directly used, or replaced with commercially available CSP LED packages, NCSP LED packages, or other LED packages, while the elevation effect may be primarily achieved by configuring the first conductive spacer 251 and the second conductive spacer 252 with appropriate thicknesses. As a result, the structure is simple, highly versatile, and low in cost.

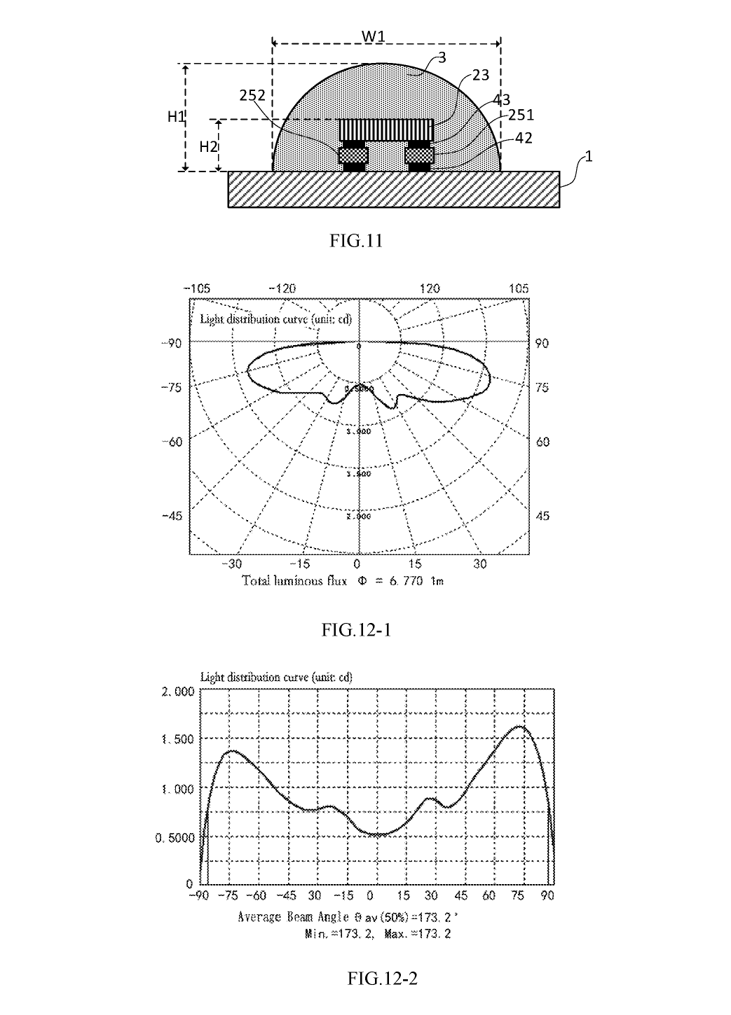

Light distribution patterns of the light-emitting device shown in FIG. 11 are illustrated in FIGS. 12-1 and 12-2, respectively. The illustrated patterns are also typical batwing-like light distribution patterns in which light intensity is highest near ±75°, a central region is dimmer than peripheral regions, and the light-emitting angle is large.

The LED chip 23 and LED packages based on the LED chip 23 in the present example may include, but are not limited to, Mini LED chips or Micro LED chips. Of course, other LED chips having dimensions larger than Mini LED chips may also be used as required.

Optionally, in the present embodiment, the light-emitting device shown in FIG. 11 may be optimized using any one of Optimization Modes 1 to 3 described above according to application requirements.

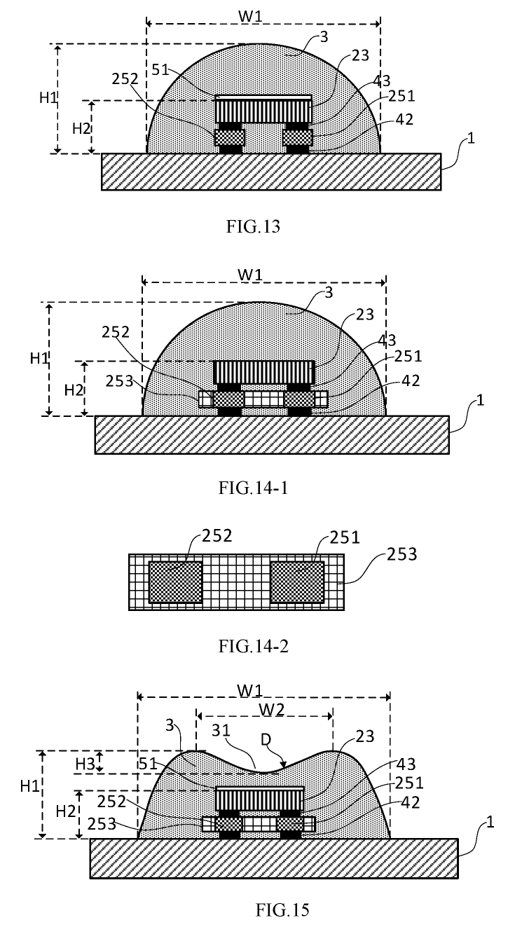

For example, referring to the light-emitting device shown in FIG. 13, which is an example of Optimization Mode 1, a first reflective layer 51 is disposed over the top light-emitting surface of the LED chip 23 based on the light-emitting device shown in FIG. 11. The first reflective layer 51 may reflect a portion of light emitted from the top light-emitting surface such that reflected light is emitted from side surfaces of the LED chip 23, thereby appropriately suppressing light intensity emitted from the top light-emitting surface of the LED chip 23, enlarging a light-emitting angle of the LED chip 23, and further optimizing the batwing-like light distribution characteristic of the light-emitting unit. Of course, it should be understood that, in the present embodiment, the light-emitting device shown in FIG. 11 may alternatively be optimized using only any other example of Optimization Mode 1 described in Embodiment 1, or Optimization Mode 2 or Optimization Mode 3, and details thereof will not be repeated herein.

Referring to FIGS. 14-1 and 14-2, in one example of the conductive spacers, the conductive spacers further include an insulating support spacer 253. The first conductive spacer 251 and the second conductive spacer 252 are respectively embedded in the insulating support spacer 253, and front surfaces and back surfaces of the first conductive spacer 251 and the second conductive spacer 252 are exposed from the insulating support spacer 253. In other words, the first conductive spacer 251 and the second conductive spacer 252 are disposed on the same insulating support spacer 253. By utilizing insulating properties of the insulating support spacer 253, electrical insulation between the first conductive spacer 251 and the second conductive spacer 252 may be achieved while also integrating the first conductive spacer 251 and the second conductive spacer 252 together, thereby facilitating subsequent mounting of the LED chip 23 and mounting of the LED light source 2 on the circuit substrate 1.

In the present application example, the insulating support spacer 253 may be opaque or, as required, may be configured as a light-transmissive spacer, thereby further improving light extraction efficiency and enlarging the light-emitting angle. Materials of the insulating support spacer 253 may include, but are not limited to, resin and glass, thereby providing low cost and ease of manufacture.

For example, referring to the light-emitting device shown in FIG. 15, based on the light-emitting device shown in FIG. 14-1, a recessed portion 31 is formed in a region of the light-emitting surface of the encapsulation lens 3 corresponding to the top light-emitting surface of the LED chip 23, and the recessed portion 31 has an arcuate surface. A first reflective layer 51 is disposed over the top light-emitting surface of the LED chip 23. In the present example, a portion of light emitted from the top light-emitting surface may be reflected such that reflected light is emitted from side surfaces of the LED chip 23, thereby appropriately suppressing light intensity emitted from the top light-emitting surface of the LED chip 23, enlarging a light-emitting angle of the LED chip 23, and further optimizing the batwing-like light distribution characteristic of the light-emitting unit.

In another example, the LED light source 2 may employ a commercially available general-purpose LED light-emitting device, such as an LED chip capable of emitting light from both side surfaces and a top surface or an LED package capable of emitting light from both side surfaces and a top surface. A region of the front surface of the circuit substrate 1 provided with pads may then be appropriately elevated.

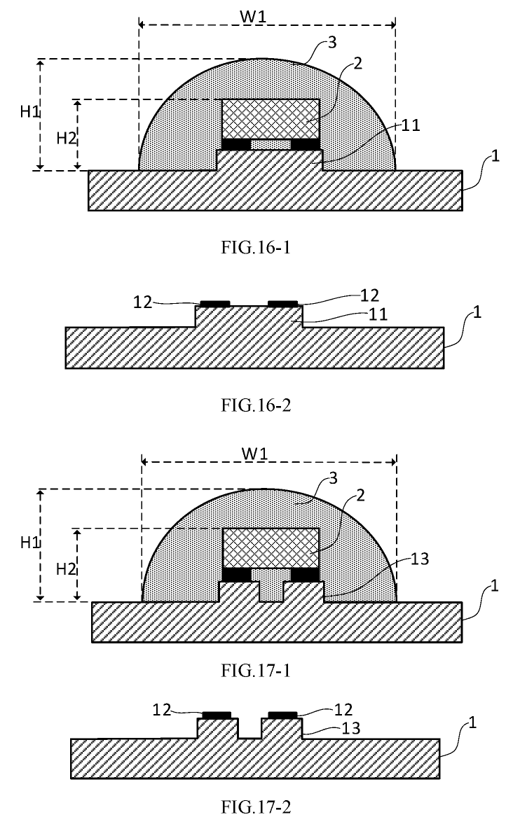

Referring to FIGS. 16-1 and 16-2, the LED light source 2 may be an LED chip or an LED package, including any one or more of a CSP LED package, an NCSP LED package, or another LED package. A region of the front surface of the circuit substrate 1 provided with pads 12 is a raised portion 11 having a raised region, and a region of the front surface of the circuit substrate 1 outside the raised portion 11 is a planar region. Two pads 12 are disposed on the raised portion 11 and electrically insulated from each other. In the example shown in FIG. 16-1, H2 is primarily determined by a thickness of the raised portion 11 and a thickness of the LED light source 2. Accordingly, by flexibly configuring the thickness of the raised portion 11, the top light-emitting surface of the LED light source 2 may be elevated to the height H2. Commercially available LED light sources 2 may also be used, thereby providing a simple structure, good versatility, and low cost.

Another example of the raised portion 11 is shown in FIGS. 17-1 and 17-2, in which the raised portion 11 includes two separated raised portions 13, and the two pads 12 are respectively disposed on the two raised portions 13. In the present example, the encapsulation lens 3 is a gel lens formed on the front surface of the circuit substrate 1 using a light-transmissive encapsulating material. The encapsulation lens 3 has a larger bonding area with the front surface of the circuit substrate 1 and surfaces of the raised portions 13, thereby providing more reliable connection and improved hermetic sealing.

Optionally, in the present embodiment, the light-emitting devices shown in FIGS. 16-1 and/or 17-1 may also be optimized using any one of Optimization Modes 1 to 3 described in Embodiment 1 according to application requirements.

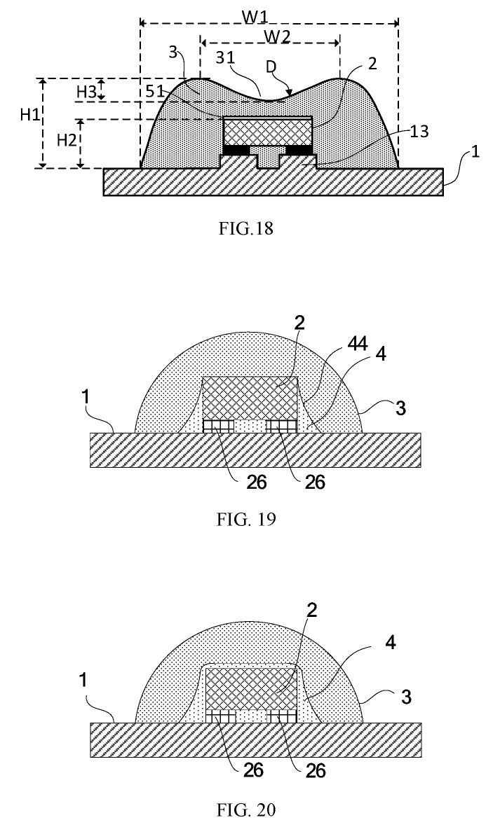

For example, referring to the light-emitting device shown in FIG. 18, a recessed portion 31 is formed in a region of the light-emitting surface of the encapsulation lens 3 corresponding to the top light-emitting surface of the LED light source, and a reflective layer 51 further covers the top light-emitting surface of the LED light source 2. The reflective layer 51 may reflect a portion of light emitted from the top light-emitting surface of the LED light source 2 such that reflected light is emitted from side surfaces of the LED light source 2, thereby appropriately suppressing light intensity emitted from the top light-emitting surface of the LED light source 2, enlarging a light-emitting angle of the LED light source 2, and optimizing the batwing-like light distribution characteristic of the light-emitting unit.

In the present embodiment, any of the above-described elevation arrangements may be used to appropriately elevate the height of the top light-emitting surface of the LED light source 2 relative to the circuit substrate 1, and various examples and embodiments may be combined according to application requirements.

It should be understood that the elevation arrangements for appropriately elevating the height of the top light-emitting surface of the LED light source 2 relative to the circuit substrate 1 in the present embodiment are not limited to the above-described examples. Regardless of which elevation arrangement is employed, as long as the ratio of H1 to H2 is 1.5 to 10 and the ratio of W1 to H1 is 0.75 to 5.3, a batwing-like light distribution characteristic may be achieved merely through the above-described combination of the LED light source 2 and the encapsulation lens 3.

### Embodiment 4

The present embodiment provides a light-emitting device. Referring to FIGS. 19 to 23, the light-emitting device includes, but is not limited to, a circuit substrate 1 and a light-emitting unit disposed on the circuit substrate 1. The light-emitting unit includes an LED light source 2 disposed on the circuit substrate 1 and an encapsulation lens 3 disposed on the front surface of the circuit substrate 1 and covering the LED light source. The LED light source 2 includes a bottom surface, a top surface, and side surfaces. The bottom surface is adjacent to the front surface of the circuit substrate 1, the top surface is away from the front surface of the circuit substrate 1 and serves as a top light-emitting surface, and the side surfaces are located between the bottom surface and the top surface and serve as side light-emitting surfaces. The encapsulation lens 3 has an arcuate light-emitting surface configured to adjust a light distribution pattern of the light-emitting unit. A top portion of the encapsulation lens 3 is convex or concave.

In the present embodiment, the LED light source 2 may be an LED chip or an LED package. The following description first uses an example in which the LED light source is the LED chip 2.

In the present embodiment, the light-emitting device further includes a filling layer 4. Electrodes 26 of the LED chip 2 are electrically connected to pads 12 on the circuit substrate 1. The LED chip 2 includes a bottom surface, a top surface, and side surfaces. The bottom surface is adjacent to the circuit substrate 1, and the top surface is away from the circuit substrate 1. The filling layer 4 fills a gap between the bottom surface and the circuit substrate 1 and is bonded to at least the bottom surface and side surfaces of the LED chip 2. The encapsulation lens 3 tightly encapsulates the filling layer 4 and the LED chip 2. Materials of the filling layer 4 and the encapsulation lens 3 are both adhesive materials. For ease of distinction, the material of the filling layer 4 is referred to herein as a first adhesive material, and the material of the encapsulation lens 3 is referred to as a second adhesive material. The first adhesive material and the second adhesive material are different from each other.

The filling layer 4 should be well bonded to epitaxial layers and a substrate of the LED chip 2, and air gaps between edge portions of the LED chip and the filling layer 4 should be avoided as much as possible. Since the second adhesive material is located at an outermost layer of the LED chip and its shape must remain stable, it cannot be fully bonded to the LED chip 2 and the circuit substrate 1 by, for example, applying pressure. If the material of the encapsulation lens 3 directly covers the LED chip, it is difficult to completely fill the gap between the circuit substrate 1 and the bottom surface of the LED chip 2, and bubbles may remain between the encapsulation lens 3 and surfaces of the substrate or LED chip.

In the present embodiment, hardness of the first adhesive material (where “hardness” refers to hardness after curing) is preferably less than or equal to hardness of the second adhesive material. During use, viscosity of the first adhesive material is preferably lower than viscosity of the second adhesive material. The first adhesive material is first combined with the LED chip. Because the first adhesive material has lower viscosity, better fluidity, and improved wettability, it can more thoroughly bond to surfaces of the LED chip 2, thereby preventing direct contact between the second adhesive material and the LED chip 2. Since the first adhesive material exhibits better bonding properties with the LED chip 2, formation of air gaps and cracking is less likely.

Because the filling layer 4 is located inside the light-emitting unit, no special shape is required therefor. Accordingly, the filling layer 4 may be brought into more complete contact with surfaces of the circuit substrate 1 and the LED chip 2 by, for example, applying pressure. Referring to FIG. 19, electrodes 26 at the bottom of the LED chip 2 and at least some edge portions of epitaxial layers of the LED chip 2 may be covered by the first adhesive material. Due to surface tension of the adhesive material, the first adhesive material itself does not form sharp corners, thereby preventing direct contact between the second adhesive material and sharp edges and corners, thus reducing a tendency of the encapsulation lens 3 to crack.

At the same time, a contact area between the second adhesive material and the circuit substrate 1 is reduced, thereby reducing a risk of delamination between the second adhesive material and the circuit substrate 1. Moreover, the encapsulation lens 3 formed of the second adhesive material still serves as an outer structural component, such that overall structural strength of the light-emitting unit remains ensured. Accordingly, in the light-emitting device of the present embodiment, the first adhesive material is first fully bonded to the bottom surface and side surfaces of the LED chip 2 to form the filling layer 4, and is then combined with the encapsulation lens 3 formed of the second adhesive material, thereby improving structural reliability while still maintaining overall structural strength.

In one preferred embodiment, the first adhesive material has a hardness less than that of the second adhesive material.

In some embodiments, the first adhesive material has a hardness ranging from Shore A30 to Shore D40. For example, the hardness of the first adhesive material may be Shore A40, Shore A50, Shore A60, Shore D10, Shore D20, Shore D30, or the like. The second adhesive material has a hardness ranging from Shore D20 to Shore D50. For example, the hardness of the second adhesive material may be Shore D20, Shore D30, Shore D40, Shore D50, or the like. The first adhesive material and the second adhesive material within the above hardness ranges provide a favorable balance between packaging stability and structural strength of the LED chip 2, thereby improving packaging reliability of the LED chip 2 and providing the light-emitting device with an extended service life.

Optionally, in the present embodiment, a contact angle between the filling layer 4 and surfaces of the circuit substrate 1 and the LED chip 2 is less than 90°, and no gap is present between the filling layer 4 and surfaces of the circuit substrate 1 and the LED chip 2. The contact angle refers to an angle measured from an interface of the circuit substrate 1 or the LED chip 2, through an interior of the filling layer 4, to an interface between the filling layer 4 and the encapsulation lens 3. A contact angle of less than 90° indicates that the first adhesive material is capable of wetting surfaces of the circuit substrate 1 and the LED chip 2 prior to curing. That is, a wetting angle (i.e., contact angle) between the liquid first adhesive material and surfaces of the circuit substrate 1 and the LED chip 2 is less than 90°.

Optionally, in the present embodiment, a viscosity of the first adhesive material prior to curing is lower than a viscosity of the second adhesive material prior to curing. In some applications, the second adhesive material is typically selected to have relatively high viscosity in order to facilitate molding. On this basis, the first adhesive material directly bonded to bottom and side surfaces of the LED chip 2 may have lower viscosity, thereby providing better flowability. Compared with the second adhesive material, the first adhesive material more readily flows into and fills a gap between the bottom surface of the LED chip 2 and the circuit substrate 1, thereby preventing formation of bubbles caused by incomplete discharge of gas between the bottom surface of the LED chip 2 and the circuit substrate 1, thus improving hermetic sealing and overall stability and service life of the light-emitting device.

Optionally, in the present embodiment, a molecular diameter of the first adhesive material is smaller than a molecular diameter of the second adhesive material.

In some embodiments, the first adhesive material has a viscosity prior to curing ranging from 1000 mPa·s to 5000 mPa·s, such as 1000 mPa·s, 2000 mPa·s, 3000 mPa·s, 4000 mPa·s, or 5000 mPa·s. The second adhesive material has a viscosity prior to curing ranging from 7000 mPa·s to 12000 mPa·s, such as 7000 mPa·s, 8000 mPa·s, 9000 mPa·s, 10000 mPa·s, 11000 mPa·s, or 12000 mPa·s. Selecting the first adhesive material and the second adhesive material within the above viscosity ranges facilitates processing of the filling layer 4 and the encapsulation lens 3 into desired shapes while also ensuring hermetic sealing and stable structural bonding.

As shown in FIG. 19, in some implementations, the first adhesive material having relatively low viscosity may form a sidewall 44 of the filling layer 4 along side surfaces of the LED chip 2, the sidewall 44 having a predetermined slope. The surface of the sidewall 44 is relatively smooth and has a relatively large surface area, thereby facilitating improved bonding with the second adhesive material. The second adhesive material having relatively high viscosity is more readily formed into a lens shape, thereby facilitating formation of the encapsulation lens 3. Accordingly, in some implementations, using the first adhesive material having hardness and viscosity both lower than those of the second adhesive material to form the filling layer 4 may further improve packaging reliability of the LED chip 2 and service life of the light-emitting device. More specifically, the first adhesive material forms, on surfaces of the LED chip 2, a sidewall 44 extending from a predetermined height along side surfaces of the LED chip 2 toward the substrate, wherein a thickness of the sidewall 44 increases in a direction away from the LED chip 2, and an outer contour of the sidewall 44 is a downwardly concave arc shape.

In some optional embodiments, the filling layer 4 does not cover a top surface of the LED chip 2, i.e., the filling layer 4 is disposed only on side surfaces and a bottom surface of the LED chip 2. The filling layer 4 may also be formed of a light-transmissive material, such that light may be emitted from side regions of the LED chip 2, thereby reducing optical influence of the filling layer 4 and providing relatively high light extraction efficiency.

As one example, when the filling layer 4 does not cover the top surface of the LED chip 2 and is disposed only on side surfaces and the bottom surface, the filling layer 4 may further include a light-reflective material or a light-diffusing material, such as silica particles or hollow glass microspheres. In another example, when the filling layer 4 does not cover the top surface of the LED chip 2 and is disposed only on side surfaces and the bottom surface, if the filling layer 4 includes a light-reflective material, light emitted from side surfaces of the LED chip 2 may be reflected such that light from the LED chip 2 is concentrated and emitted only from the top surface, thereby satisfying light distribution requirements of certain specialized application scenarios.

Optionally, in order to maximize bonding between the encapsulation lens 3 and the LED chip 2, the filling layer 4 may completely encapsulate the LED chip 2. As shown in FIG. 20, the filling layer 4 completely surrounds the LED chip 2 on surfaces thereof, and the encapsulation lens 3 covers the filling layer 4 so as to encapsulate both the LED chip 2 and the filling layer 4. In this configuration, the encapsulation lens 3 is bonded to the filling layer 4 without directly contacting the LED chip 2. Since the surface of the LED chip 2 is covered by the relatively soft first adhesive material, bonding therebetween is improved. The filling layer 4 completely covering the LED chip 2 further reduces a possibility of forming air gaps. In addition, because both the first adhesive material and the second adhesive material are adhesive materials, they can also bond well to each other, thereby providing improved overall hermetic sealing.

Furthermore, because the filling layer 4 completely covers the LED chip 2, even if the outer encapsulation lens 3 cracks or is otherwise damaged such that its protective function fails, the filling layer 4 may still provide a certain degree of encapsulation protection, thereby improving reliability of the light-emitting device.

It should be understood that, when the filling layer 4 covers the top surface of the LED chip 2, the filling layer 4 is light-transmissive. In the present embodiment, the encapsulation lens 3 is also formed of a light-transmissive material. Since light is emitted through the filling layer 4, various optical materials may additionally be incorporated into the filling layer 4 in some implementations. For example, the filling layer 4 may include a light color conversion material, including but not limited to phosphor and/or quantum dots, and/or a light diffusion material, such as silica particles or hollow glass microspheres.

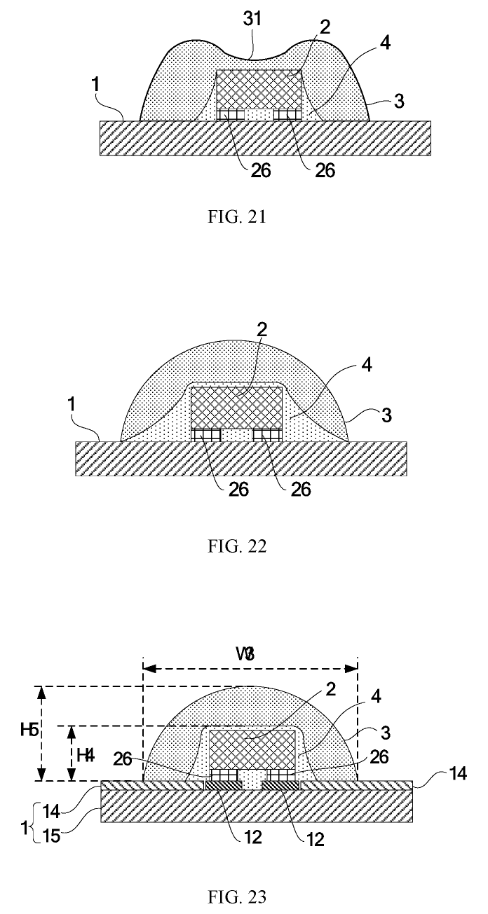

The encapsulation lens 3 has an arcuate light-emitting surface so as to adjust a light distribution pattern of the light-emitting unit. The present embodiment does not limit an external shape of the encapsulation lens. For example, in the example shown in FIG. 19, the encapsulation lens 3 may be formed into a hemispherical or substantially hemispherical shape, such that a top portion of the encapsulation lens 3 is convex. As another example, as shown in FIG. 21, a recessed portion 31 recessed toward the top surface of the LED chip 2 may be formed in a region of the light-emitting surface of the encapsulation lens 3 corresponding to the top surface of the LED chip 2. A surface of the recessed portion 31 may be arcuate, and regions outside the recessed portion 31 may also be arcuate. The recessed portion 31 forms a concave surface at a top portion of the encapsulation lens 3, thereby increasing an incident angle at which light emitted from the top surface of the LED chip 2 reaches the recessed portion 31. By utilizing a characteristic that total internal reflection readily occurs when light travels from an optically denser medium to an optically less dense medium (e.g., air), a propagation direction of such light may be altered, thereby enlarging a light-emitting angle of the LED chip 2 and appropriately suppressing light intensity in a top-surface region of the LED chip 2. In some implementations, such a configuration may optimize the light-emitting unit to form a batwing-like light distribution curve. In other embodiments, the encapsulation lens 3 may alternatively be designed in other shapes.

In some embodiments, the filling layer 4 is bonded to the surface of the circuit substrate 1, and a coverage area of the encapsulation lens 3 (i.e., a projected area onto the surface of the circuit substrate 1) is greater than a coverage area of the filling layer 4. The encapsulation lens 3 is also bonded to the surface of the circuit substrate 1 around the filling layer 4. Direct bonding of the filling layer 4 and the encapsulation lens 3 to the circuit substrate 1 enhances bonding with the circuit substrate 1, thereby improving hermetic sealing of the package. Since the second adhesive material used for the encapsulation lens 3 is relatively hard and also has relatively high viscosity, stress generated after bonding to a relatively large area of the circuit substrate 1 is relatively high. In the present embodiment, however, under the same coverage area of the encapsulation lens 3, a contact area between the encapsulation lens 3 and the circuit substrate 1 is reduced due to the presence of the filling layer 4, thereby reducing a tendency for delamination between the encapsulation lens 3 and the circuit substrate 1 during use under thermal shock, vibration, or other external forces.

In practical applications, the bonding area between the filling layer 4 and the circuit substrate 1 and the bonding area between the encapsulation lens 3 and the circuit substrate 1 may both be configured according to actual requirements. In some examples, the encapsulation lens 3 may not contact the circuit substrate 1, and the coverage area of the filling layer 4 may be not less than the coverage area of the encapsulation lens 3.

For example, in the example shown in FIG. 22, the coverage area of the filling layer 4 is equal to the coverage area of the encapsulation lens 3, and the filling layer 4 completely covers the LED chip 2. The encapsulation lens 3 is bonded only to the filling layer 4, and the package structure of the LED chip 2 is coupled to the circuit substrate 1 only through the filling layer 4, thereby providing good bonding therebetween. This example minimizes contact between the second adhesive material of the encapsulation lens 3 and the circuit substrate 1. The filling layer 4 preferably uses the relatively soft first adhesive material, which has a hardness less than that of the second adhesive material, and is less likely to delaminate from the circuit substrate 1, thereby providing improved package reliability. In actual manufacturing, it may be difficult to make the coverage area of the filling layer 4 exactly equal to the coverage area of the encapsulation lens 3. Therefore, the coverage area of the filling layer 4 may also exceed the coverage area of the encapsulation lens during manufacture.

In the present embodiment, the LED chip 2 may include, but is not limited to, a Mini LED chip, a Micro LED chip, or an LED chip of another size. The emission wavelength of the LED chip 2 may be any suitable wavelength. The light-emitting device may include one or more light-emitting units. The LED chips 2 in the light-emitting device may be of a single color or may be mixed in multiple colors. The base material 15 of the circuit substrate 1 may include, but is not limited to, ceramic, resin, or glass. The circuit substrate 1 may be a rigid substrate or a flexible substrate, such as, but not limited to, a rigid Printed Circuit Board (PCB) or a Flexible Printed Circuit (FPC) board. Other adhesive materials may also be used in some examples. To further improve reliability, the first adhesive material and the second adhesive material may be selected to have similar stress characteristics and good mutual bonding properties, for example, by using adhesive materials of the same type, such as silicone-based adhesive materials including organic silicone adhesive.

A specific example is further provided below. Referring to FIG. 23, the circuit substrate 1 includes a base material 15 and a solder mask ink layer 14 disposed on a surface of the base material 15. The solder mask ink layer 14 protects circuits on the base material 15 to prevent short circuits, and improves oxidation and corrosion resistance as well as insulation performance. The LED chip 2 is bonded to pads 12 exposed on a surface of the circuit substrate 1 through a bonding layer, which is not shown in the figure. The bonding layer may be formed of a bonding material such as solder paste or conductive adhesive. Regions other than the pads 12 may be covered and protected by the solder mask ink layer 14. The filling layer 4 and the encapsulation lens 3 may be directly bonded to the solder mask ink layer 14. The solder mask ink layer 14 is tightly bonded to the filling layer 4 and the encapsulation lens 3, thereby providing waterproofing and hermetic sealing effects. By controlling a bonding area between the encapsulation lens 3 and the solder mask ink layer 14 through the filling layer 4, delamination between the encapsulation lens 3 and the circuit substrate 1 may also be mitigated.

In the present example, the filling layer 4 completely covers the LED chip 2. Even if delamination occurs between the encapsulation lens 3 and the solder mask ink layer 14 and causes the protective function of the encapsulation lens 3 to completely fail, the cooperation between the filling layer 4 and the solder mask ink layer 14 can still provide effective hermetic sealing and waterproofing performance, thereby preventing the LED chip 2 from being directly exposed. In addition, in the foregoing example, the encapsulation lens 3 is also bonded to the circuit substrate 1, and the encapsulation lens 3, which has relatively high viscosity and hardness, provides higher bonding strength with the circuit substrate 1. Accordingly, the encapsulation lens 3 can provide a more secure bonding effect and also contributes to stability of the package structure.

In the present example, the filling layer 4 may completely cover the LED chip 2, similar to forming an adhesive film around the LED chip 2. A height H4 of the filling layer 4 may range from 50 μm to 300 μm, such as 50 μm, 100 μm, 200 μm, or 300 μm, and may also be set according to a height of the LED chip 2. In the present example, the encapsulation lens 3 is specifically an encapsulation lens having a substantially hemispherical surface. A bottom diameter W3 of the encapsulation lens 3 may range from 3 mm to 8 mm, such as 4 mm, 5 mm, 6 mm, or 7 mm, and a height H5 thereof may range from 1.5 mm to 4 mm, such as 2 mm, 2.5 mm, 3 mm, or 3.5 mm.

The filling layer 4 is bonded to the surface of the circuit substrate 1 at the bottom and around the LED chip 2. In the region where the filling layer 4 is provided, the encapsulation lens 3 in the present example has a diameter greater than that of the filling layer 4. At a position corresponding to the LED chip 2, the encapsulation lens 3 is bonded only to the filling layer 4, and around the filling layer 4, the encapsulation lens 3 is directly bonded to the surface of the circuit substrate 1. It should be noted that, in the present example, the projections of the filling layer 4 and the encapsulation lens 3 onto the circuit substrate 1 are assumed to be circular, and their diameters are used to reflect their respective coverage areas. However, in other examples, the specific shapes of the filling layer 4 and the encapsulation lens 3 may be other shapes.

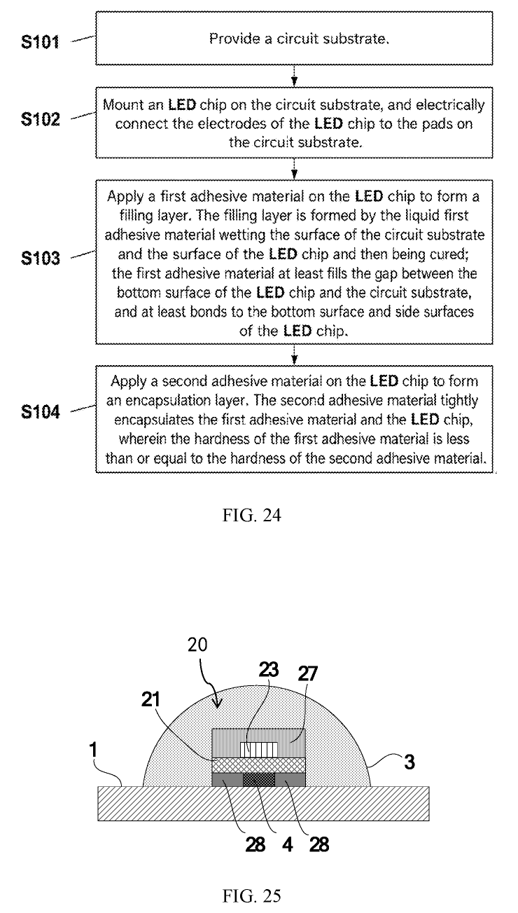

The present embodiment further provides a method for manufacturing a light-emitting device. Referring to FIG. 24, the method provided in the present embodiment includes, but is not limited to, the following steps.

S101: providing a circuit substrate.

S102: disposing an LED chip on the circuit substrate, wherein electrodes of the LED chip are electrically connected to pads on the circuit substrate.

The LED chip includes a bottom surface, a top surface, and side surfaces. The bottom surface is adjacent to the circuit substrate, and the top surface is away from the circuit substrate. After the LED chip is placed on the circuit substrate, conductive bonding may be formed between the pads of the circuit substrate and the LED chip using a bonding material such as solder paste or conductive adhesive.

S103: applying a first adhesive material at the LED chip to form a filling layer. The filling layer is formed by curing the liquid first adhesive material after the liquid first adhesive material wets the surface of the circuit substrate and the surface of the LED chip. The first adhesive material at least fills a gap between the bottom surface of the LED chip and the circuit substrate and is bonded to at least the bottom surface and side surfaces of the LED chip.

It should be noted that, when the liquid first adhesive material wets the surface of the circuit substrate and the surface of the LED chip, a wetting angle, i.e., a contact angle, between the first adhesive material and the surfaces of the circuit substrate and the LED chip is less than 90°. After curing, the contact angle between the filling layer and the surfaces of the circuit substrate and the LED chip may be less than 90°. In other embodiments, when the filling layer is formed, pressure or other means may also be applied so that the first adhesive material is sufficiently bonded to the surfaces of the circuit substrate and the LED chip, thereby filling the gap between the circuit substrate and the bottom surface of the LED chip.

To ensure hermetic sealing and waterproofing, the filling layer in the present embodiment is formed directly on the circuit substrate. After the LED chip is disposed, the first adhesive material may be applied at or beside the LED chip by, for example, dispensing. Because the first adhesive material has certain flowability, it can flow to the bottom surface of the LED chip and fill the gap between the LED chip and the circuit substrate. In some implementations, by controlling the amount of the first adhesive material, the degree of coverage over the LED chip may also be controlled. For example, a larger amount of the first adhesive material may completely cover the LED chip.

S104: applying a second adhesive material at the LED chip to form the encapsulation lens 3. The second adhesive material tightly encapsulates the first adhesive material and the LED chip, wherein the hardness of the first adhesive material is less than or equal to the hardness of the second adhesive material.

The encapsulation lens 3 of the present embodiment is likewise formed directly on the circuit substrate 1. After the LED chip is disposed, the second adhesive material may be applied at the LED chip by, for example, dispensing. The second adhesive material can tightly encapsulate the filling layer and the LED chip, such that no gap is present, thereby providing high reliability and improved hermetic sealing and preventing external moisture from entering the encapsulation lens 3 and damaging the LED chip.

It should be understood that the method for manufacturing the light-emitting device according to the present embodiment may be used to manufacture the light-emitting devices illustrated in FIGS. 19 to 23.

The foregoing examples are described using the LED chip as the LED light source 2. Alternatively, the LED chip may be replaced with an LED package as another example of the LED light source 2, as described below.

Referring to the light-emitting device shown in FIG. 25, the LED light source 2 in the light-emitting device is an LED package 20. The LED package 20 includes an LED support, an LED chip 23, and an encapsulant 27 covering the LED chip 23 on the LED support 21. The LED support includes a support substrate 21 and electrodes 28. The electrodes 28 are electrically connected to the circuit substrate 1. The LED package 20 includes a bottom surface, a top surface, and side surfaces. The bottom surface is adjacent to the circuit substrate 1, and the top surface is away from the circuit substrate 1. The filling layer 4 fills a gap between the bottom surface and the circuit substrate 1. The encapsulation lens 3 tightly encapsulates the filling layer 4 and the LED light source, and both the filling layer 4 and the encapsulation lens 3 are bonded to the circuit substrate 1.

In the LED package of the present example, the LED chip 23 is disposed on the support substrate 21 and is surrounded by the encapsulant 27 without any other blocking structure. The encapsulant 27 is formed of a light-transmissive adhesive material, and light emitted from the top and side surfaces of the LED chip directly enters the encapsulation lens after passing through the encapsulant 27.

The filling layer 4, the encapsulation lens 3, and the encapsulant 27 are all formed of adhesive materials. For ease of distinction, in the embodiments of the present application, the material of the filling layer 4 is referred to as a first adhesive material, the material of the encapsulation lens 3 is referred to as a second adhesive material, and the material of the encapsulant 27 is referred to as a third adhesive material. The first adhesive material and the second adhesive material are different from each other.

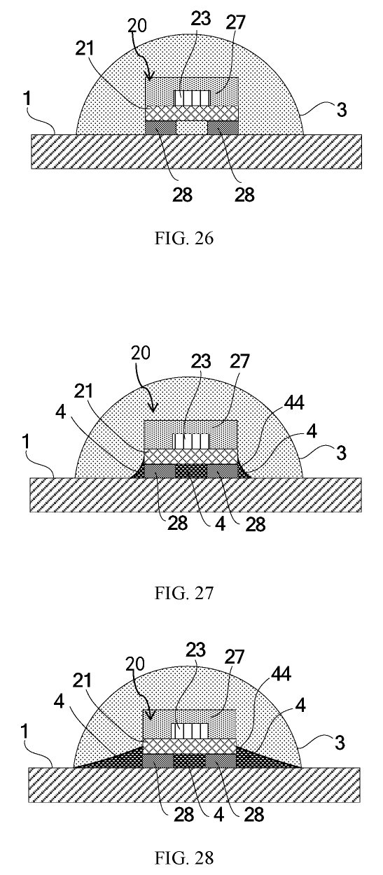

As a comparison with the light-emitting device shown in FIG. 25, referring to the light-emitting device shown in FIG. 26, no filling layer is provided between the LED light source 2 and the circuit substrate. The encapsulation lens 3 is bonded to the circuit substrate 1 around the LED light source 2 and at the bottom surface of the LED light source 2, except for positions blocked by the electrodes 28, and therefore has a relatively large bonding area with the circuit substrate 1. To meet requirements for structural strength and moldability of the encapsulation lens 3, the material of the encapsulation lens 3 usually has relatively high hardness and relatively high viscosity. This may result in relatively large stress when the second adhesive material is bonded to a large area of the circuit substrate 1, and delamination may easily occur between the second adhesive material and the circuit substrate 1 during use under thermal shock, vibration, or other external forces.

In addition, to form stable hermetic protection, the material of the encapsulation lens 3 should encapsulate the LED light source 2 as seamlessly as possible. However, because the material of the encapsulation lens 3 has relatively high viscosity and poor flowability, it is difficult during manufacture for the material to sufficiently wet surfaces of the circuit substrate 1 and the LED light source 2. Further, because the encapsulation lens 3 is located at the outermost layer of the LED light source 2 and its shape must remain stable to achieve a specific optical effect, it also cannot be sufficiently bonded to the LED light source 2 and the circuit substrate 1 by, for example, applying pressure. Therefore, it is difficult for the second adhesive material to completely fill a gap between the circuit substrate 1 and the bottom surface of the LED package, and bubbles may remain between the encapsulation lens 3 and surfaces of the circuit substrate 1 or the LED light source 2.

Compared with the light-emitting device shown in FIG. 26, the light-emitting unit in the present example further includes the filling layer 4, and the filling layer 4 at least fills the gap between the bottom surface of the LED package 20 and the circuit substrate 1. In the light-emitting device shown in FIG. 26, the filling layer 4 only fills a position between the electrodes 28 on the bottom surface of the LED light source. In other embodiments, the coverage area of the filling layer 4 is not limited thereto.

In the present embodiment, the filling layer 4 uses a material having better flowability, thereby facilitating filling of the gap between the bottom of the LED package 20 and the circuit substrate 1. Because the filling layer 4 is located inside the light-emitting unit, no special shape is required for the filling layer 4. During manufacture, the filling layer may be sufficiently bonded to the surface of the circuit substrate and the surface of the LED package 20 by, for example, applying pressure. In a region where the filling layer 4 is provided, the encapsulation lens 3 does not directly contact the circuit substrate 1. Because the first adhesive material has a hardness less than or equal to that of the second adhesive material and because the filled area is relatively small, the generated stress is relatively small, so delamination from the circuit substrate 1 is less likely to occur. In addition, when the coverage area of the encapsulation lens 3 remains unchanged, the contact area between the second adhesive material and the circuit substrate 1 is reduced, thereby also reducing the risk of delamination between the second adhesive material and the circuit substrate 1. The encapsulation lens 3, namely the second adhesive material, still serves as an outer structural component, so the overall structural strength of the light-emitting unit and the moldability requirements of the encapsulation lens can still be satisfied.

Accordingly, the light-emitting device of the present example can improve structural reliability while maintaining overall structural strength.

In some embodiments, as shown in FIG. 27, the coverage area of the encapsulation lens 3, namely the projected area onto the surface of the circuit substrate 1, is greater than the coverage area of the filling layer 4, and the encapsulation lens 3 is bonded to the surface of the circuit substrate 1 around the filling layer 4. Thus, both the filling layer 4 and the encapsulation lens 3 are bonded to the circuit substrate 1.

In some embodiments, as shown in FIGS. 27 and 28, the provided area of the filling layer 4 is greater than a projected area of the LED package 20 onto the circuit substrate 1, so as to completely encapsulate the electrodes 28 of the LED package 20. The filling layer 4 can provide additional hermetic protection for the electrodes 28 of the LED package 20, and can also provide a certain degree of protection when the encapsulation lens 3 fails, so that the electrodes 28 of the LED package 20 are not directly exposed. In practical applications, the bonding area between the filling layer 4 and the circuit substrate 1 and the bonding area between the encapsulation lens 3 and the circuit substrate 1 may both be configured according to actual requirements. In the foregoing embodiments, by controlling the bonding areas of the filling layer 4 and the encapsulation lens 3 with the circuit substrate 1, the bonding strength between the overall structure of the light-emitting unit and the circuit substrate 1 can be adjusted, thereby achieving a balance between bonding strength and stability according to actual requirements.

Referring to FIGS. 27 and 28, in some implementations, the first adhesive material having relatively low viscosity may form a sidewall of the filling layer 4 having a certain slope at a region near the bottom surface along a side surface of the LED package 20. The contact angle between the sidewall and the surfaces of the circuit substrate 1 and the LED package is less than 90°, and the sidewall has a relatively smooth surface and a relatively large surface area, thereby facilitating better bonding with the second adhesive material. The second adhesive material having relatively high viscosity is more readily formed into a lens shape. Using the first adhesive material having hardness and viscosity both lower than those of the second adhesive material to form the filling layer 4 can improve structural reliability of the LED package and service life of the light-emitting device. The first adhesive material forms, on a surface of the LED package 20, a sidewall 44 extending from a predetermined height along a side surface of the LED package 20 toward the substrate, wherein a thickness of the sidewall 44 increases in a direction away from the LED package 20, and an outer contour of the sidewall 44 is a downwardly concave arc shape. The filling layer 4 may contact the circuit substrate 21 or the encapsulant 27 of the LED package 20.

Referring to the light-emitting device shown in FIG. 28, the coverage area of the filling layer 4 is equal to the coverage area of the encapsulation lens 3. The encapsulation lens 3 is bonded to the filling layer 4 and to exposed portions of the LED package 20, namely portions not covered by the filling layer 4, but is not bonded to the circuit substrate 1. This maximally avoids contact between the second adhesive material of the encapsulation lens 3 and the circuit substrate 1. The filling layer 4 uses the relatively soft first adhesive material, which is less likely to delaminate from the circuit substrate 1, thereby providing good structural reliability of the light-emitting unit. In the present example, the third adhesive material is preferably the same as the second adhesive material, thereby providing good bonding compatibility.

In the present example, the filling layer 4 may be formed of a light-transmissive adhesive material or a non-light-transmissive adhesive material. When the filling layer 4 is light-transmissive, optical materials may also be provided in the filling layer 4. For example, a light diffusion material, such as silica particles or hollow glass microspheres, may be provided in the filling layer 4. When the filling layer 4 is non-light-transmissive, the filling layer 4 may be formed of a material capable of reflecting light or may include an optical material capable of reflecting light. Because the filling layer 4 is disposed at the bottom surface of the LED package, the filling layer 4 may be used to reflect light from the bottom of the LED package 20 toward the top surface or side surfaces of the LED package 20, thereby improving light utilization efficiency.

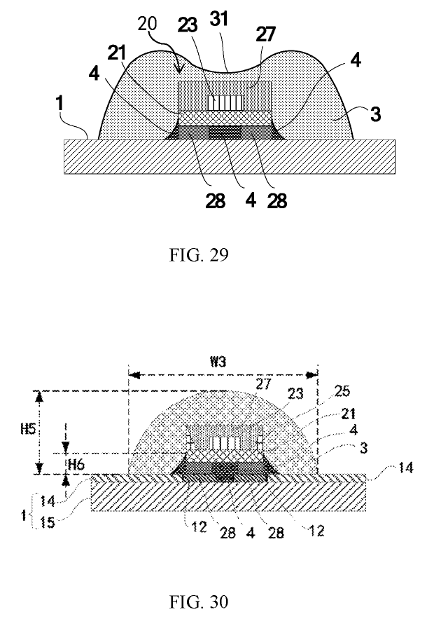

Referring to the light-emitting device shown in FIG. 29, a recessed portion 31 recessed toward the top surface of the LED light source may be formed in a region of the light-emitting surface of the encapsulation lens 3 corresponding to the top surface of the LED package 20. The surface of the recessed portion 31 may be arcuate, and regions outside the recessed portion 31 may also be arcuate. The recessed portion 31 forms a concave surface at the top portion of the encapsulation lens 3, thereby increasing an incident angle at which light emitted from the top surface of the LED light source reaches the recessed portion 31. By utilizing a characteristic that total internal reflection readily occurs when light travels from an optically denser medium to an optically less dense medium, such as air, a propagation direction of this portion of light may be altered, thereby enlarging a light-emitting angle of the LED package 20 and appropriately suppressing light intensity in a top-surface region of the LED package 20. In some implementations, the light-emitting unit may thereby be optimized to form a batwing-like light distribution characteristic. In other embodiments, the encapsulation lens 3 may alternatively be designed in other shapes.

In the present embodiment, the LED package may include, but is not limited to, a Mini LED package, a Micro LED package, or an LED package of another size. The emission wavelength of the LED package may be any suitable wavelength. The light-emitting device may include one or more light-emitting units. The LED packages in the light-emitting device may be of a single color or may be mixed in multiple colors. The first adhesive material, the second adhesive material, and the third adhesive material in the present embodiment may be silicone-based adhesive materials, such as organic silicone adhesive. Other adhesive materials may also be used in some examples. To further improve reliability, the first adhesive material, the second adhesive material, and the third adhesive material may be selected to have similar stress characteristics and good mutual bonding properties, for example, by using adhesive materials of the same type, such as silicone-based adhesive materials.

A specific example is further provided below. Referring to FIG. 30, the circuit substrate 1 includes a base material 15 and a solder mask ink layer 14 disposed on a surface of the circuit substrate 1. The solder mask ink layer 14 protects circuits on the base material 15 to prevent short circuits and improves oxidation and corrosion resistance and insulation performance. The LED package 20 is bonded to pads 12 exposed on a surface of the circuit substrate 1 through a bonding layer, which is not shown in the figure. The bonding layer may be formed of a bonding material such as solder paste or conductive adhesive. Regions other than the pads 12 may be covered and protected by the solder mask ink layer 14. The filling layer 4 and the encapsulation lens 3 may be directly bonded to the solder mask ink layer 14. The solder mask ink layer 14 is tightly bonded to the filling layer 4 and the encapsulation lens 3, thereby providing waterproofing and hermetic sealing effects. By controlling the bonding area between the encapsulation lens 3 and the solder mask ink layer 14 through the filling layer 4, delamination between the encapsulation lens 3 and the circuit substrate 1 may also be mitigated.

The LED package 20 includes an LED support, an LED chip 23, and an encapsulation lens 3. In the present example, the LED support includes a support substrate 21 and a cup-shaped enclosure 25 having light-transmissive side surfaces. That is, both the top surface of the LED package, namely the surface away from the circuit substrate 1, and the side surfaces of the LED package can emit light. Continuing to refer to FIG. 30, the support substrate 21 may be a non-light-transmissive substrate, or preferably may be a light-transmissive substrate to improve light extraction efficiency of the light-emitting unit, and may be selected according to requirements. The cup-shaped enclosure 25 is disposed on the support substrate 21, and lead electrodes are disposed on the support substrate 21. At least one LED chip 23 is disposed at the bottom of the cup-shaped enclosure 25 and is bonded, namely electrically connected, to the lead electrodes on the support substrate 21. The encapsulant 27 is filled in the cup-shaped enclosure 25 and covers the LED chip 23. The encapsulant 27 may be tightly bonded to an inner wall of the cup-shaped enclosure 25 and surfaces of the LED chip 23 to form a hermetic package and improve light extraction efficiency. The encapsulant 27 is formed of the third adhesive material, which in this example is specifically a silicone-based adhesive material. It should be understood that the encapsulant 27 is light-transmissive. The encapsulant 27 may be transparent, or may include optical materials, such as a light color conversion material including, but not limited to, phosphor and/or quantum dots, and/or a light diffusion material such as silica particles or hollow glass microspheres.

In the present example, both the first adhesive material used for the filling layer 4 and the second adhesive material used for the encapsulation lens 3 are silicone-based adhesive materials. Preferably, the first adhesive material has both a hardness, referring to hardness after curing, and a viscosity, referring to viscosity before curing, lower than those of the second adhesive material. The first adhesive material has better flowability and better bonding properties with the LED package than the second adhesive material, and the formed filling layer 4 is relatively flat and may be relatively thin. In the present example, the filling layer 4 fills the gap between the LED package and the circuit substrate 1 and covers a larger area around the LED package. The filling layer 4 completely encapsulates the electrodes 28 of the LED package to provide additional protection, while limiting the bonding area between the encapsulation lens 3 and the circuit substrate 1 so as to adjust the overall bonding strength.

For example, a height H6 of the filling layer 4 may range from 50 μm to 300 μm, such as 50 μm, 100 μm, 150 μm, 200 μm, or 300 μm. The height H6 of the filling layer 4 may also be set according to a height of the LED light source. In some applications, the height H6 of the filling layer 4 does not exceed a distance between the bottom surface of the LED chip 23 and the circuit substrate 1; that is, the filling layer 4 is lower than the bottom surface of the LED chip 23. This allows light emitted from the side surfaces of the LED package to substantially avoid passing through the filling layer 4, thereby reducing the optical influence of the filling layer 4 and also reducing the number of media layers through which the light must pass.

In the present example, the encapsulant 27 completely covers the LED chip 23. Even if delamination occurs between the encapsulation lens 3 and the solder mask ink layer 14 and causes the protective function of the encapsulation lens 3 to completely fail, the cooperation between the filling layer 4 and the solder mask ink layer 14 can still provide effective hermetic sealing and waterproofing protection for the LED chip 23. In addition, in the foregoing example, the encapsulation lens 3 is bonded to the circuit substrate 1, and the encapsulation lens 3, which has relatively high viscosity and hardness, provides higher bonding strength with the circuit substrate 1. Accordingly, the encapsulation lens 3 can provide a more secure bonding effect and also contributes to stability of the package structure.

In other embodiments, the filling layer 4 may also completely cover the LED package 20.

In addition to the LED chip and LED package described in the above examples, the LED light source 2 in the present embodiment may also be replaced with other types of LED light sources, and details thereof will not be repeated herein.

The present application further provides a display screen, not shown in the drawings. The display screen may be applied to, but is not limited to, televisions, curtain walls, vehicle-mounted devices, mobile devices, and wearable devices. The display screen includes a backlight source board and a display panel, and the display panel is disposed on a light-emitting side of the backlight source board. The backlight source board includes the light-emitting device according to any one of the foregoing embodiments. In the present embodiment, the circuit substrate of the light-emitting device is provided with a plurality of light-emitting units, and the plurality of light-emitting units may be arranged in a rectangular array or a linear array.

The present embodiment further provides a lighting device, not shown in the drawings. The lighting device may be applied to outdoor lighting, such as roads and stadiums, and may also be applied to indoor lighting, such as offices, gymnasiums, libraries, and classroom lighting. The lighting device may also be applied to plant lighting, handheld lighting, and the like. The lighting device includes a housing and an illumination light source disposed in the housing. The illumination light source is the light-emitting device according to any one of the foregoing embodiments. The circuit substrate of the light-emitting device may be provided with one or more light-emitting units as required.

It should be understood that the application of the present invention is not limited to the examples described above. Those of ordinary skill in the art may make improvements or modifications based on the foregoing description, and all such improvements and modifications shall fall within the scope of the appended claims of the present invention.

What is claimed is:

1. A light emitting device, comprising:
a circuit substrate; and
a light emitting unit disposed on a front surface of the circuit substrate;
wherein the light emitting unit comprises: an LED light source disposed on the front surface of the circuit substrate and electrically connected to corresponding pads on the front surface of the circuit substrate; and an encapsulation lens disposed on the front surface of the circuit substrate and covering the LED light source, the encapsulation lens having an arcuate light-emitting surface configured to adjust a light distribution pattern of the light emitting unit;
wherein a ratio of a first maximum distance H1 between the light-emitting surface of the encapsulation lens and the front surface of the circuit substrate to a second maximum distance H2 between a top light-emitting surface of the LED light source and the front surface of the circuit substrate is 1.5 to 10, and a ratio of a first maximum width W1 of the encapsulation lens to the first maximum distance H1 is 0.75 to 5.3.

2. The light emitting device of claim 1, wherein the light-emitting surface of the encapsulation lens includes a recessed portion corresponding to the top light-emitting surface of the LED light source, the recessed portion being an arcuate concave surface, and wherein a ratio of a second maximum width W2 of the recessed portion to a maximum depth H3 thereof is 0.62 to 50.

3. The light emitting device of claim 1, wherein the light emitting unit further comprises a reflective layer at least partially covering the top light-emitting surface of the LED light source.

4. The light emitting device of claim 1, further comprising a filling layer, wherein the filling layer at least fills a gap between a bottom surface of the LED light source and the circuit substrate and is bonded to at least the bottom surface and side surfaces of the LED light source;
wherein the encapsulation lens covers the filling layer and the LED light source; and
wherein the filling layer is formed of a first adhesive material, the encapsulation lens is formed of a second adhesive material different from the first adhesive material, and the first adhesive material has a hardness less than or equal to that of the second adhesive material.

5. The light emitting device of claim 4, wherein the filling layer forms an inclined surface along a side surface of the LED light source.

6. The light emitting device of claim 4, wherein the first adhesive material is a light-transmissive material forming the filling layer surrounding the LED light source, and wherein the encapsulation lens is disposed outside the filling layer and has a coverage area greater than that of the filling layer so as to bond to a surface of the circuit substrate.

7. The light emitting device of claim 4, wherein the filling layer forms an inclined sidewall extending toward the circuit substrate along a side surface of the LED light source, the inclined sidewall having a thickness that gradually increases in a direction away from the LED light source, and an outer contour of the inclined sidewall being concavely curved.

8. The light emitting device of claim 4, wherein the first adhesive material has a hardness ranging from Shore A30 to Shore D40, and the second adhesive material has a hardness ranging from Shore D20 to Shore D50.

9. The light emitting device of claim 1, wherein the LED light source comprises a micro LED chip, and the micro LED chip is a Mini LED chip or a Micro LED chip.

10. The light emitting device of claim 1, wherein the LED light source is an LED package including an LED support, an LED chip, a cup-shaped enclosure, and an encapsulating adhesive layer;
wherein the LED chip is disposed within a region surrounded by the cup-shaped enclosure, and the encapsulating adhesive layer fills the cup-shaped enclosure and covers the LED chip.

11. The light emitting device of claim 1, further comprising a lifting structure disposed on the circuit substrate and electrically connected to the pads, wherein the LED light source is disposed on the lifting structure.

12. The light emitting device of claim 11, wherein the lifting structure comprises a plurality of electrically conductive pads electrically insulated from one another, the plurality of electrically conductive pads being disposed between the LED light source and the circuit substrate.

13. The light emitting device of claim 12, wherein the lifting structure further comprises an insulating support spacer, and the plurality of electrically conductive pads are disposed on the insulating support spacer.

14. The light emitting device of claim 11, wherein the light-emitting surface of the encapsulation lens includes a recessed portion corresponding to the top light-emitting surface of the LED light source, the recessed portion being an arcuate concave surface, and wherein a ratio of a second maximum width W2 of the recessed portion to a maximum depth H3 thereof is 0.62 to 50.

15. The light emitting device of claim 11, wherein the light emitting unit further comprises a reflective layer disposed over the top light-emitting surface of the LED light source, the reflective layer being configured to reflect a portion of light emitted from the top light-emitting surface such that reflected light is emitted from a side surface of the LED light source.

16. The light emitting device of claim 11, further comprising a filling layer, wherein the filling layer at least fills a gap between a bottom surface of the LED light source and the circuit substrate and is bonded to at least the bottom surface and side surfaces of the LED light source;
wherein the encapsulation lens covers the filling layer and the LED light source; and
wherein the filling layer is formed of a first adhesive material, the encapsulation lens is formed of a second adhesive material different from the first adhesive material, and the first adhesive material has a hardness less than or equal to that of the second adhesive material.

17. A light emitting device, comprising:
a circuit substrate; and
a light emitting unit disposed on the circuit substrate;
wherein the light emitting unit comprises an LED light source and an encapsulation lens covering the LED light source, the encapsulation lens having an arcuate light-emitting surface;
wherein the circuit substrate includes a raised region and a planar region outside the raised region, pads being disposed on the raised region, and the LED light source being disposed on the pads on the raised region and electrically connected to the circuit substrate; and
wherein a ratio of a first maximum distance H1 between the light-emitting surface of the encapsulation lens and an upper surface of the planar region to a second maximum distance H2 between a top light-emitting surface of the LED light source and the upper surface of the planar region is 1.5 to 10.

18. The light emitting device of claim 17, wherein the light-emitting surface of the encapsulation lens includes a recessed portion corresponding to the top light-emitting surface of the LED light source, the recessed portion being an arcuate concave surface, and wherein a ratio of a second maximum width W2 of the recessed portion to a maximum depth H3 thereof is 0.62 to 50.

19. The light emitting device of claim 17, wherein the raised region comprises two separated raised portions, and the pads are respectively disposed on the two separated raised portions.

20. The light emitting device of claim 19, wherein the encapsulation lens is a gel lens formed on the circuit substrate and covering the two separated raised portions.
